(19) United States
(12) Patent Application Publication
(10) Pub. No.: US 2005/0224844 A1
(43) Pub. Date: Oct. 13, 2005

(54) Solid-state image sensing device

(76) Inventor: Akira Mizuguchi, Suwa-shi (JP)

Correspondence Address: EDWARDS & ANGELL, LLP, P.O. Box 5587, Boston, MA, 02205-5874, US

(21) Appl. No.: 11/010,084

(22) Filed: Dec. 8, 2004

(30) Foreign Application Priority Data
Dec. 26, 2003 (JP) 2003-432407

(51) Int. Cl. H01L 29/768

(52) U.S. Cl. 257/233; 257/291; 257/292

(57) ABSTRACT

A drain region 8 of a modulation transistor TM, which outputs a pixel signal in accordance with a photoelectric charge while a threshold voltage of a channel between a source region 7 and the drain region 8 is controlled by the photoelectric charge stored in a modulating well 5, is formed with a high concentration N+ layer 8a surrounding the collecting well 4 and the modulating well 5, and an N− layer accommodating the N+ layer 8a in the periphery of a ring gate 6 to become a diffusion layer with lower concentration than the N+ layer, thereby avoiding effects of the crystal defects of the drain region 8.

### BACKGROUND OF THE INVENTION

1. Field of the Invention

The present invention relates to a solid-state image sensing device having high image quality and low power consumption.

2. Related Art

There are two types of image sensors, namely the charge coupled device (CCD) type and the CMOS type, as solid-state image sensing devices to be installed in mobile phones and so on. In general, the CCD type of image sensors has higher image quality while the CMOS type of image sensors has lower power consumption and lower process costs. In recent years, the MOS type of solid-state image sensing devices featuring the threshold voltage modulation method, which achieves both high image quality and low power consumption, have been proposed. The MOS type of solid-state image sensing devices featuring the threshold voltage modulation method are disclosed in, for example, Japanese Unexamined Patent Publication No. 2001-177085 (JP '085).

The image sensors have sensor cells in a matrix and repeat three states, namely initialization, storing, and reading, to obtain image outputs. The image sensor disclosed by JP '085 has unit pixels each equipped with a light emitting diode for performing the storage step and a transistor for performing the reading out step.

FIG. 7 is a schematic cross-sectional view showing the image sensor disclosed in JP '085. In the image sensor shown in FIG. 7, a light receiving diode 111 and an insulated gate field effect transistor 112 both formed on an N-type diffusion layer 118 are disposed adjacent to each other on a substrate 100 for each of the unit pixels. A gate electrode 113 of the transistor 112 is formed like a ring, and a source region 114 is formed in an opening section in the center of the gate electrode 113.

A charge (a photoelectric charge) generated in response to the light entering through an opening area of the light receiving diode 111 is transferred to a P-type well region 116 below the gate electrode 113 and then stored in a carrier pocket 117 formed therein. The threshold voltage of the transistor 112 changes in accordance with the photoelectric charge stored in the carrier pocket 117. Thus, a signal (a pixel signal) corresponding to the incident light can be read out from the source region 114 of the transistor 112.

Note that, in the device of JP '085, outputs of the unit pixels arranged in the same column are arranged to be read out via a common source line. The voltage applied to the gate of the transistor 112 is controlled line by line, thus a predetermined one of the unit pixels connected to the common source line can be read out. Namely, relatively high gate voltage is applied to the transistor 112 of the unit pixel (the selected pixel) to be read out while relatively low gate voltage is applied to the transistor 112 of the unit pixel (the non-selected pixel) not to be read out. Since the output of the transistor applied with the higher gate voltage is higher than the output of the transistor applied with the lower gate voltage, the output of the selected pixel can be obtained.

Incidentally, the transistor 112 shown in FIG. 7 has a low concentration drain structure (Lightly Doped Drain; LDD structure), in which n-type low concentration drain region 115a surrounds the periphery of the ring shaped gate electrode 113. In an outer periphery section of the low concentration drain region 115a, there is formed a high concentration drain region 115b so as to avoid the light receiving section and to be connected to the low concentration drain region 115a, and the low concentration drain region 115a is integrally formed with the impurity region 115 of the surface layer of the well section 116 in the light receiving diode 111.

Therefore, in the transistor 112 shown in FIG. 7, the structure must have the low concentration drain region 115a formed inside the high concentration drain region 115b and more shallowly (more nearly to the gate electrode 113) than the high concentration drain region 115b, with the lower part of the high concentration drain region 115b connected to the P-type well region 116 below the gate electrode 113. Thus, the probability increases that the dark current is generated when the carrier is stored in the P-type well region 116 owing to crystal defects remaining in the interfacial surface of the N-type high concentration drain region 115b.

Note that, in a process of forming a diffusion layer by ion implantation, the implanted ions lose energy by colliding with atoms in the substrate and finally stop by the energy loss caused by the diffusion with the lattice atoms. Therefore, the greater the mass of the ion to be implanted is and the greater the acceleration energy is, the more the crystal defects are generated in the interfacial surface where the ion stops, and the crystal defects remain unrecovered even by a thermal treatment executed after the ion implantation.

Generally, since, for forming the higher concentration drain region, impurity ions with greater mass than for the lower concentration drain region are ion-implanted with greater energy (e.g., ion-implantation with arsenic, with about 80 Kev of acceleration energy, and with about 2.0×10¹⁵ pcs/cm² of dose amount), it cannot be avoided that a large number of crystal defects are generated in the interfacial surface of the high concentration drain region 115b. Therefore, characteristics of modulation transistors may be degraded to make the image quality worse because the dark current caused by the crystal defects are generated in the PN junction with the P-type well region 116, which leads to the pixel defects and decreases the production yield.

Note that, although crystal defects are similarly generated in the N-type high concentration source region 114 adjacent to the P-type well region 116, the defect density is low and accordingly, the effect thereof is small because the source region is generally formed using phosphorous having smaller mass and higher diffusion coefficient than arsenic, the acceleration energy and the dose amount are less, and the effective area is smaller than the drain region.

### SUMMARY OF THE INVENTION

The present invention addresses the above problem, and has an advantage of providing a solid-state image sensing device capable of improving characteristics of a transistor formed adjacent to a photoelectric transducer element by avoiding effects of crystal defects generated in the interfacial surface of the drain region of the transistor thereby obtaining high quality images.

A solid-state image sensing device according to one embodiment of the present invention is a solid-state image sensing device including a photoelectric transducer element and a transistor formed adjacent to the photoelectric transducer element, comprising: a first well of a second conduction type, and formed on the substrate and in an area where the photoelectric transducer element is formed; a second well of a first conduction type, and formed above the first well; a third well of the second conduction type, and formed on the substrate, in an area where the transistor is formed, and adjacent to the first well; a fourth well of the first conduction type, and formed above the third well and adjacent to the second well; a gate with an opening, and formed above the fourth well; a source of the second conduction type, and formed below the opening; a drain of the second conduction type, and formed on the periphery of the second well and the fourth well; and a diffusion layer of the second conduction type, and formed so as to accommodate the drain, and having impurity concentration lower than impurity concentration of the drain.

According to the above configuration, a charge generated in the photoelectric transducer element forming area in accordance with the incident light is transferred to and then stored in the fourth well in the transistor forming area adjacent to the second well in the photoelectric transducer element forming area, and the threshold voltage of the channel under the gate above the fourth well is controlled in accordance with the charge held therein, thus outputting from the transistor a pixel signal in accordance with the photoelectric charge. In this case, since the drain of the transistor is accommodated by the diffusion layer having impurity concentration lower than the impurity concentration of the drain, effects of the crystal defects remaining in the interfacial surface can be avoided, thereby improving the characteristics of the transistor to obtain higher quality images.

Further, the diffusion layer of the second conduction type can be formed on an area excluding the second well.

According to such a configuration, the drain of the transistor never erodes the second well in the photoelectric transducer element forming area, thus the effects of the crystal defects in the drain interfacial surface can be avoided without degrading the photosensitivity.

Further, the diffusion layer of the second conduction type can be formed so as to accommodate the drain in the periphery of the gate.

According to the configuration described above, the crystal defects in the interfacial surface of the drain in the periphery of the gate can be suppressed to the drain conductive type of neutral region by the low concentration diffusion layer. Thus, the effects of the crystal defects can be avoided, thereby improving the characteristics of the transistor to obtain higher quality images.

Further, the solid-state image sensing device further can comprise: a diffusion layer of the first conduction type, and formed below the gate and in the fourth well, and having impurity concentration higher than the fourth well.

According to the above configuration, while avoiding the effects of the crystal defects in the interfacial surface of the drain, the photoelectric charges can more efficiently be stored or held in the diffusion layer with higher impurity concentration in the fourth well, thus enhancing the conversion efficiency between the photoelectric charges and the voltage.

### BRIEF DESCRIPTION OF THE DRAWINGS

FIG. 1 is a cross-sectional view showing a cross-sectional shape of a solid-state image sensing device.

FIG. 2 is a plan view showing a planer shape of an unit sensor sell of the solid-state image sensing device.

FIG. 3 is a circuit block diagram showing an overall structure of an element by an equivalent circuit.

FIGS. 4(A) through 4(D) are process charts for explaining a method of manufacturing the element.

FIGS. 5(A) through 5(C) are process charts for explaining a method of manufacturing the element.

FIGS. 6(A) and 6(B) are plan views for explaining a mask area of a resist mask.

FIG. 7 is a schematic cross-sectional view showing the image sensor disclosed in the Related Art.

### DETAILED DESCRIPTION OF THE PREFERRED EMBODIMENTS

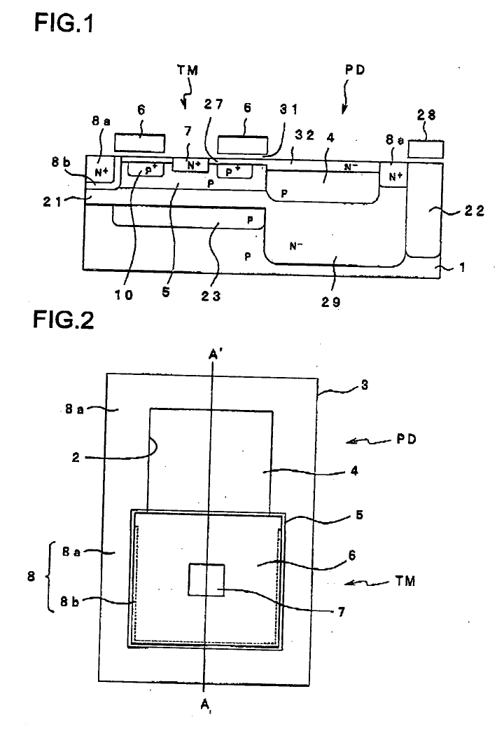

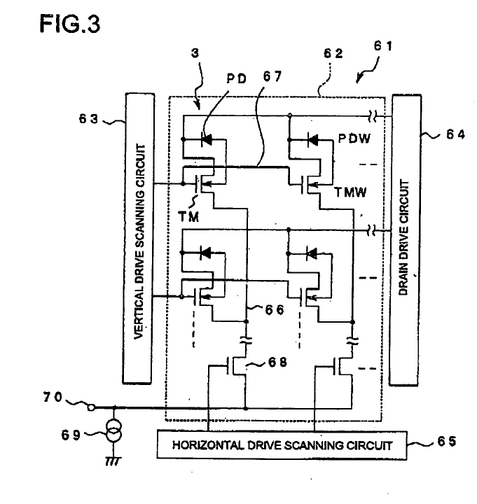

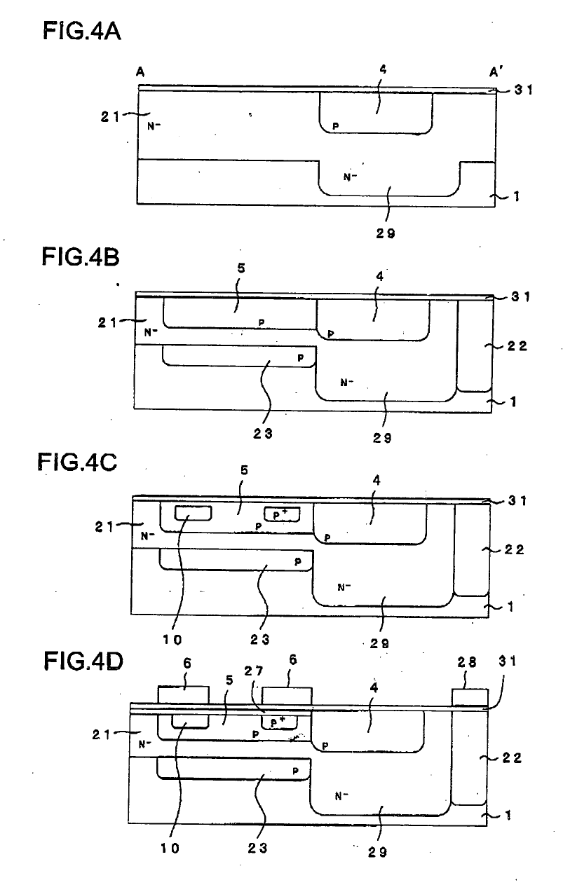

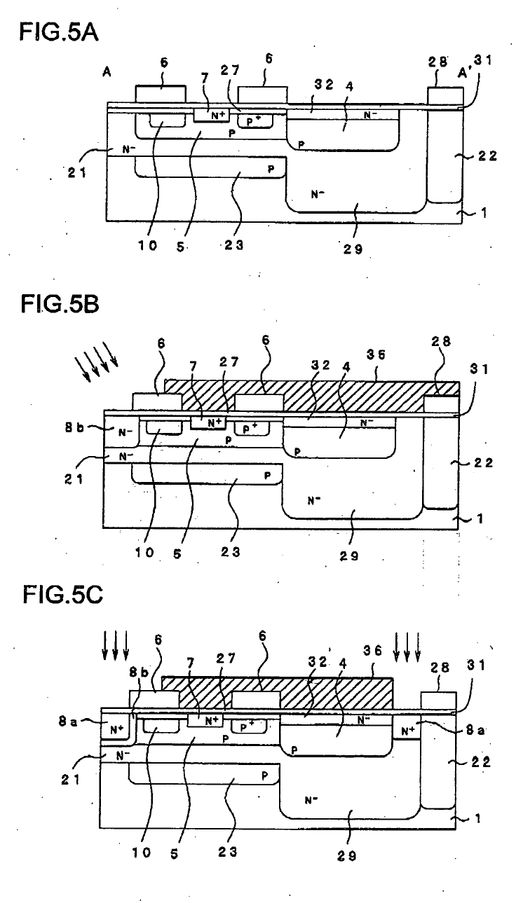

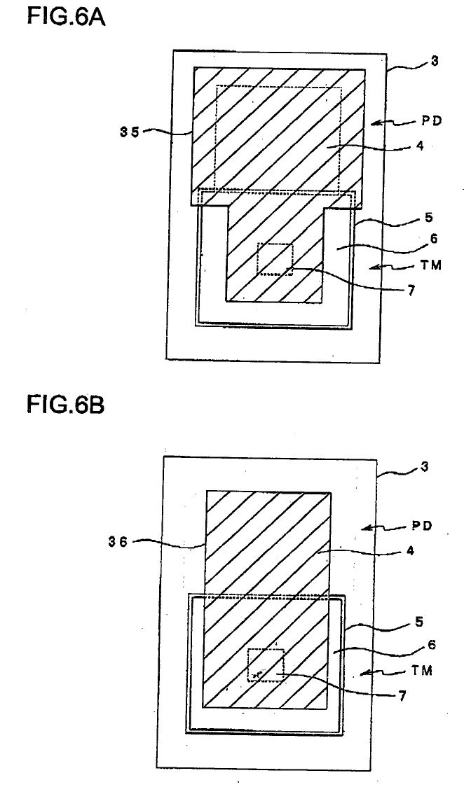

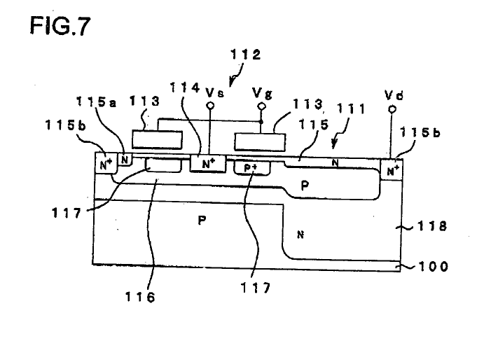

Hereinafter, an embodiment of the present invention is described in detail with reference to the accompanying drawings. FIGS. 1 through 6 relate to one embodiment of the present invention, wherein FIG. 1 is a cross-sectional view showing a cross-sectional shape of a solid-state image sensing device, FIG. 2 is a plan view showing a planar shape of one sensor cell of the solid-state image sensing device, FIG. 3 is a circuit block diagram showing a overall structure of the cell by an equivalent circuit, FIGS. 4A through 4D and 5A through 5C are process charts for explaining a manufacturing process of the cell, and FIGS. 6A and 6B are explanatory plan views showing a mask area of a resist mask.

Sensor Cell Structure

The solid-state image sensing device of the present invention comprises a sensor cell array composed of sensor cells, the unit pixels, arranged in a matrix. Each of the sensor cells captures and then stores photoelectric charges generated in response to the incident light to output a pixel signal having a level corresponding to the stored photoelectric charges. By arranging the sensor cells in a matrix, the image signals of one frame can be obtained.

Firstly, a structure of each of the sensor cells is described with reference to FIGS. 1 and 2. FIG. 2 shows one of the sensor cells. And, in the present embodiment, positive holes are used as the photoelectric charges, for example. An alternative structure in which electrons are used as the photoelectric charges can also be adopted. Note that FIG. 1 shows a cross-sectional structure of the cell when cut along the A-A′ line in FIG. 2.

As shown in the plan view of FIG. 2, a photodiode PD and a modulation transistor TM are provided adjacent to each other in the sensor cell 3, the unit pixel. As the modulation transistor TM, for example, an N channel depression type MOS transistor can be used. The unit pixel having a substantially rectangular shape is slanted with respect to columns or rows of the matrix arrangement, and is not separated in a single row but is separated with respect to each row.

In a photodiode PD forming area, which is a photoelectric transducer element forming area, an opening area 2 is provided on a surface of a substrate 1, and in a relatively shallow area of the substrate 1, there is formed a well 4 (hereinafter referred to as a collecting well), which is a P-type well occupying an area broader than the opening area 2, for collecting photoelectric charges generated by the photoelectric transducer element. An N-type diffusion layer 32 as a pinning layer is formed on the substrate 1 and above the collecting well 4.

Apart from the collecting well 4 with a predetermined distance and in the modulation transistor TM forming area, there is formed a well 5 (hereinafter referred to as a modulating well), which is a P-type well, for controlling the modulation transistor TM in accordance with the photoelectric charges collected by the collection well and sent therefrom.

On the substrate 1 and above the modulating well 5, there is formed a ring shaped gate 6 (a ring gate) are formed, and the source region 7, which is a high concentration N-type region, is formed in an area adjacent to the surface of the substrate 1 and corresponding to the center opening of the ring gate 6. An N-type drain region 8 is formed around the ring gate 6. As described below, the drain region 8 is composed of, only in the periphery of the modulation transistor TM, an N+ layer 8a with high concentration and an N− layer 8b with lower concentration than the N+ layer 8a and surrounding the N+ layer 8a. A drain contacting region (not shown in the drawings) is provided adjacent to the surface of the substrate 1 and in a predetermined position of the high concentration N+ layer 8a.

The modulating well 5 controls the threshold voltage of a channel of the modulation transistor TM. Inside the modulating well 5 and below the ring gate 6, there is formed a carrier pocket 10 (See FIG. 1.), the P-type high concentration region. The modulation transistor TM is composed of the modulating well 5, the ring gate 6, the source region 7, and the drain region 8, and is arranged so that the threshold voltage of the channel changes in accordance with the charges stored in the modulating well 5 (the carrier pocket 10).

When the drain region 8 and the diffusion layer 32 are positively biased with the drain voltage applied thereto, in an area below the opening area 2 of the photodiode PD, the depletion layer spreads from the interfacial surface between the diffusion layer 32 and the collecting well 4 throughout the collecting well 4 and reaches N-type wells 21 and 29. Meanwhile, the depletion layer spreads from the interfacial surface between the substrate 1 and the N-type well 21 throughout the N-type wells 21 and 29 to reach the collecting well 4. The photoelectric charges are generated in the depletion area in accordance with the light entering through the opening area 2. And, as described above, it is arranged that the generated photoelectric charges are collected by the collecting well 4.

The charges collected by the collecting well 4 are transferred to the modulating well 5 and then stored in the carrier pocket 10. Thus, the source potential of the modulation transistor TM is determined in accordance with an amount of charges transferred to the modulating well 5, namely the incident light to the photodiode PD.

Cross-Section of the Sensor Cell

The cross-sectional structure of the sensor cell 3 is further described in detail with reference to FIG. 1. FIG. 1 shows the photodiode PD forming area and the modulation transistor TM forming area in a single unit pixel (a cell). An isolation area 22 for element separation is provided between the photodiode PD forming area of one cell and the modulation transistor TM forming area of another cell adjacent to the one cell with a row spacing of the matrix arrangement. A gate electrode 28 is formed on a substrate surface side of the isolation area 22.

The N-type well 21 is formed in a relatively deep area of the substrate 1 and throughout the P-type substrate 1. The N-type well 21 is formed to a relatively deep area of the substrate to form an N− layer. An N-type collecting well 29 as a first well and a P-type collecting well 4 as a second well are formed in the photodiode forming area. The diffusion layer 32, which is an N− pinning layer, is formed on the surface side of the substrate above the collecting well 4.

Meanwhile, in the modulation transistor TM forming area, a P-type buried layer 23 is formed on the substrate 1. On the N-type well 21 as a third well on the P-type buried layer 23, there is formed a P-type modulating well 5 as a fourth well. The carrier pocket 10 derived from P+ diffusion is formed inside the modulating well 5.

In the modulation transistor TM forming area, the ring gate 6 is formed on the surface of the substrate via a gate oxidized film 31, and an N-type diffusion layer 27 composing a channel is formed on the surface of the substrate and under the ring gate 6. The N+ diffusion layer is formed on the surface of the substrate and corresponding to the center of the ring gate 6 to compose the source region 7. Further, the N-type diffusion layer is formed on the surface of the substrate and corresponding to the periphery of the ring gate 6 to compose the drain region 8. The N-type diffusion layer 27 forming the channel is connected to both the source region 7 and the drain region 8.

In the present embodiment, the drain region 8 is formed, only in the periphery of the modulation transistor TM, as a double diffused drain structure (a DDD structure) composed of the N+ layer 8a which is a high concentration drain region and the N− layer 8b which is a low concentration diffusion layer with lower impurity concentration then the N+ layer 8a. The impurity concentration of the N− layer 8b is higher than the N-type well 21 reaching a relatively deep area of the substrate, and substantially the same as the N-type diffusion layer 32 (the pinning layer) on the collecting well 4.

The low concentration N− layer 8b is formed so as to avoid the collecting well 4 so as not to erode the P-type collecting well 4 in the photodiode forming area, thereby, among the cells adjacent to each other in the same row of the matrix arrangement, the high concentration N+ layer 8a is provided between the collecting wells of the respective cells, on the one hand, in the periphery of the ring gate 6, the low concentration N− layer 8b is arranged to surround the high concentration N+ layer 8a to be connected to the modulating well 5, on the other hand.

Namely, the high concentration N+ layer 8a, which is to become the drain region of the modulation transistor TM, is connected to the modulating well not directly but via the low concentration N− layer 8b. Owing to the low concentration N− layer 8b, the crystal defect area remaining in the interfacial surface of the N+ layer 8a can be changed to be a drain conductive type of neutral area in which it is controlled to be the N-type layer in the depletion layer of the PN junction with the P-type modulating well 5, thus generation of the dark current can be suppressed by reducing an amount of the charges captured by the defects in the modulating well 5, whereby the source potential of the modulation transistor TM can be set in accordance with the incident light to the photodiode PD.

Circuit Configuration of the Whole Device

Hereinafter, a circuit configuration of the whole of the solid-state image sensing device according to the present embodiment is described with reference to FIG. 3.

The solid-state image sensing device 61 comprises a sensor cell array 62 including the sensor cell 3 shown in FIG. 2 and circuits 63 through 65 for driving each sensor cell 3 of the sensor cell array 62. The sensor cell array 62 is composed of the cells 3 disposed in a matrix. The sensor cell array 62 includes, for example, 640×480 of cells 3 and an area (an OB area) for an optical black (OB). When including the OB area, the sensor cell array 62 is composed of, for example, 712×500 of cells 3.

Each of the sensor cells 3 includes the photodiode PD for performing photoelectrical transformation and the modulation transistor TM for detecting and then reading out the light signal. The photodiode PD generates charges (photoelectric charges) in accordance with the incident light, and the generated charges are collected inside the collection well 4 (corresponding to the node PDW in FIG. 3). The photoelectric charges collected in the collecting well 4 are transferred to and then stored in the carrier pocket 10 in the modulating well 5 (corresponding to the node TMW in FIG. 3).

Since storing the photoelectric charges in the carrier pocket 10 is equivalent to changing the back gate bias in the modulation transistor TM, the threshold voltage of the channel changes in accordance with the amount of charges in the carrier pocket 10. Thus, the source voltage of the modulation transistor TM can be set in accordance with the charges in the carrier pocket 10, namely, the brightness of the incident light to the photodiode PD.

As described above, each of the cells 3 performs storing, transferring, reading out, or discharging in response to drive signals applied to the ring gate 6, the source region 7, or the drain region 8 of the modulation transistor TM. As shown in FIG. 3, various sections of the cell 3 are arranged to be provided with various signals supplied from a vertical scanning circuit 63, a drain drive circuit 64, and a horizontal scanning circuit 65. The vertical scanning circuit 63 supplies agate line 67 of the each row with a scanning signal while the drain drive circuit 64 applies the drain region 8 of the each column with the drain voltage. Further, the horizontal scanning circuit 65 supplies a switch 68 connected to the each source line 66 with a drive signal.

Each cell 3 is provided corresponding to one of the intersections between a plurality of source lines 66 arranged in the horizontal direction in the sensor cell array 62 and a plurality of gate lines 67 arranged in the vertical direction. In each cell 3 of teach line arranged in the horizontal direction, the ring gate 6 of the modulation transistor TM is connected to the common gate line 67, and in each cell 3 of each column arranged in the vertical direction, the source of the modulation transistor TM is connected to the common source line 66.

By supplying one of the plurality of gate lines 67 with the on-signal (selected gate voltage), the cells commonly connected to the gate line 67 to which the on-signal is supplied are simultaneously selected, and the image signals are output from the sources of the selected cells via the respective source lines 66. The vertical scanning circuit 63 supplies the gate line 67 with the on-signal while sequentially shifting the on-signal in a single frame duration. The image signals for a single line from the cells of the line supplied with the on-signal are read out from the source lines 66 and then supplied to the switches 68 simultaneously. The image signals for one line is sequentially output (line output) from the switch 68 by the horizontal scanning circuit 65.

The switch 68 connected to each of the source lines 66 is connected to a image signal output terminal 70 via a common constant current source 69 (a load circuit). Since the source of the modulation transistor TM of the each sensor cell 3 is connected to the constant current source 69, a source follower circuit for the sensor cell 3 is configured.

As described above, the solid-state image sensing device 61 is arranged to control the voltage applied to the gate of the modulation transistor in both the selected row and the unselected row with the sources of all of the modulation transistors in the same row connected commonly to detect the source voltages of the modulation transistors of the desired line. Namely, the potential (Vg) of the gate electrode in all of the pixels of the selected row is set to a high level while the potential (Vg) of the gate electrode in the unselected row is set to the ground potential.

Further, in order to cancel any differences between the unit pixels or various noises, in the reading out process, subsequently to the light signal reading out operation of the selected row, the pixels of the selected row are initialized with applied potentials to the pixels in the unselected row maintained, and then the threshold voltages in the initialized state are subsequently read out. And then, differential signals between the threshold voltages in accordance with the photoelectric charges and the threshold voltages in the initialized state are calculated to output the net light signal components as the image signals.

Specifically, light detection operation and photoelectric charge collection operation of the photodiode PD, and reading out operation of the modulation transistor TM is performed as follows.

Firstly, a low gate voltage is applied to the ring gate 6 of the modulation transistor TM, and a voltage (VDD) necessary for the transistor operation is applied to the drain region 8, for example, a voltage of about 2 to 3 volts. Thus, the P-type wells 4 and 5 are depleted. Further, an electric field is generated between the drain region 8 and the source region 7.

Electron-hole pairs (photoelectric charges) are generated in response to the light entering via the opening area 2 of the photodiode PD into the silicon. In this case, when the generated holes reach the depleted P-type well 4 and 5, the holes are transferred along the potential gradient to the carrier pocket 10 containing P-type impurity with high concentration, and then stored therein.

The threshold voltage of the modulation transistor TM changes in accordance with the photoelectric charge stored in the carrier pocket 10. In this condition, the ring gate 6 of the selected pixel is applied with a gate voltage (a selected gate voltage) of, for example, about 2 to 3 volts while the drain region 8 is applied with a voltage VDD of, for example, about 2 to 3 volts. Further, a constant current is supplied to the source region 7 of the modulation transistor TM by the constant current source 69. Thus, the modulation transistor TM forms the source follower circuit, in which the source potential varies in accordance with the variation of the threshold voltage of the modulation transistor TM caused by the photoelectric charges, and accordingly the output voltage varies. Therefore, an output in accordance with the incident light can be obtained.

In the initialization process, the residual charges in the carrier pocket 10, the collecting well 4, and the modulating well 5 are discharged. For example, a high positive voltage of 7 to 8 volts is applied to the drain region 8 and the ring gate 6 of the modulation transistor TM. Since the N-type well 21 below the modulating well 5 is thin, and the high concentration P-type buried layer 23 is formed on a portion of the substrate 1 facing to the N-type well 21, the effect of the voltage applied to the ring gate 6 acts only on the modulating well 5 and adjacent areas thereto. In other words, a rapid potential change occurs in the modulating well 5, and a strong electric field to sweep out the photoelectric charges to the substrate 1 side is applied mainly to the modulating well 5, whereby the residual photoelectric charges can more surely be discharged to the substrate 1 with a lower reset voltage.

After the initialization process, a relatively low voltage value of the unselected gate voltage is applied to the ring gates of the unselected pixels while a relatively high value of the selected gate voltage is applied to the ring gates 6 of the selected pixels. And, the output signals of the selected pixels after the initialization process is obtained from the commonly connected source line 66.

In the present embodiment, the modulation transistor TM comprises the drain region 8 of the DDD structure in which the high concentration N+ layer 8a is surrounded by the low concentration N− layer 8b. By the drain region 8 with the DDD structure, an electric field in the horizontal direction can be reduced to prevent the degradation by the hot carrier, and to prevent the charges in the modulating well 5 from being captured by the residual crystal defects in the interfacial surface of the high concentration N+ layer 8a, thus obtaining the higher image quality by improving the characteristics of the modulation transistor TM.

<Process>

Hereinafter, a manufacturing process of the element is described with reference to the process charts shown in FIGS. 4(A) through 4(D), and 5(A) through 5(C). FIGS. 4(A) through 4(D), and 5(A) through 5(C) show cross-sections along the cutting line A-A′ shown in FIG. 2. In these charts, arrows above the substrate denote that an ion implantation is executed.

As shown in FIG. 4(A), the N-type well 21 is formed by ion implanting, for example, the phosphorous (P) ion to a prepared P substrate 1. Subsequently, in the surface side of the substrate 1 and in the photodiode forming area, the P-type collecting well 4 is formed by ion implanting, for example, the boron ion, and the N-type collecting well 29 is formed by ion implanting, for example, the phosphorous ion. Further, the gate oxidized film 31 is formed on the surface of the substrate 1 by thermal oxidization.

Subsequently, as shown in FIG. 4(B), the isolation region 22 for separating the elements is formed. Further, the P-type buried layer 23 is formed in the modulation transistor forming area by deeply ion implanting the P-type impurity using a predetermined resist mask. Further, the P-type modulating well 5 is formed on the surface layer of the N-type well 21 by shallowly ion implanting the P-type impurity using the same resist mask.

Subsequently, as shown in FIG. 4(C), the carrier pocket 10 composed of a high concentration P+ diffusion layer is formed inside the modulating well 5 below the ring gate 6. Subsequently, the N-type diffusion layer 27 for obtaining the channel of the modulation transistor TM is formed adjacent to the surface of the substrate and above the carrier pocket 10. Subsequently, as shown in FIG. 4(D), the ring gate 6 of the modulation transistor TM is formed on the gate oxidization film 31, and the gate electrode 28 is formed on the isolation region 22.

Subsequently, as shown in FIG. 5(A), the resist mask covering the photodiode forming area is formed, and the source region 7 is formed by, for example, implanting N+ impurity using phosphorous using the resist mask and the ring gate 6 as a mask. Subsequently, after removing the resist mask, a new resist mask covering the source region 7 is formed to form the N-type diffusion layer 32 on the surface of the substrate and in the photodiode forming area.

Subsequently, as shown in FIG. 5(B), a resist mask 35 covering a larger area than the collecting well 4 of the photodiode forming area and a slightly smaller area than the outer periphery of the ring gate 6 is formed, and the N-type impurity is ion implanted downward with an angle using the resist mask 35 and the ring gate 6 as masks to form the low concentration N− layer 8b only in a predetermined region including a region below the ring gate 6.

Subsequently, after removing the resist mask 35, as shown in FIG. 5(C), a resist mask 36 covering the photodiode forming area and an area slightly smaller than the outer periphery of the ring gate 6 is formed, and the high concentration N+ layer 8a is formed shallower in the low concentration N− layer 8b by, for example, N+ impurity implantation using arsenic using the resist mask 36 and the ring gate 6 as masks. Thus, the high concentration N+ layer 8a is surrounded by the low concentration N− layer 8b.

The resist mask 35 for forming the low concentration N− layer 8b in the drain region 8 comprises, as shown in FIG. 6(A), a mask area broader than the collecting well 4 and a mask area covering the source region 7 of the modulation transistor TM and being set smaller than the outer periphery of the ring gate 6.

Further, the resist mask for 36 for forming the high concentration N+ layer 8a in the drain 8 comprises, as shown in FIG. 6(B), a mask area being set to cover substantially the same area as the collecting well 4 without eroding the area of the collecting well 4 taking the diffusion during the ion implantation into consideration, and a mask area having the same width as the mask area and covering the source region of the modulation transistor TM. Namely, the resist mask 35 is arranged to mask the collecting well 4 with a broader area than the resist mask 36.

In the present embodiment, firstly, by using the resist mask 35, ion implantation to the lower part of the outer periphery of the ring gate 6 can be realized without eroding the collecting well 4, the low concentration N− layer 8b can be formed between the ring gates 6 except the collecting wells 4 of the adjacent cells in the same row. Subsequently, by the ion implantation using the resist mask 36, the high concentration N+ layer 8a can be formed on the periphery of the collecting well 4, and the high concentration N+ layer 8a surrounded by the low concentration N− layer 8b on the periphery of the ring gate 6 can be formed. Thus, the drain region 8 having DDD structure can be formed in the modulation transistor TM.

Note that, although, in the above descriptions, an example in which the high concentration N+ layer 8a is formed after forming the low concentration N− layer 8b is explained, the high concentration N+ layer 8a can firstly be formed followed by forming the low concentration N− layer 8b.

As described above, in the present embodiment, by forming the drain region 8 of the modulation transistor TM with DDD structure, the dark current caused by the crystal defects can be prevented in the PN junction surface between the drain region 8 and the modulating well 5. Thus, the characteristics of the modulation transistor TM can be improved to realize higher image quality, and generation of the pixel defects can be suppressed to enhance the manufacturing yield. Further more, since the low concentration N− layer 8b for accommodating the high concentration N+ layer 8a is formed on the periphery of the ring gate 6 except the collecting well 4 when forming the drain region 8 having the DDD structure, it is prevented that the photodiode PD forming area shrinks to degrade the sensitivity.

1. A solid-state image sensing device including a photoelectric transducer element and a transistor formed adjacent to the photoelectric transducer element, comprising:
a substrate of a first conduction type;
a first well of a second conduction type, and formed on the substrate and in an area where the photoelectric transducer element is formed;
a second well of the first conduction type, and formed above the first well;
a third well of the second conduction type, and formed on the substrate, in an area where the transistor is formed, and adjacent to the first well;
a fourth well of the first conduction type, and formed above the third well and adjacent to the second well;
a gate with an opening, and formed above the fourth well;
a source of the second conduction type, and formed below the opening;
a drain of the second conduction type, and formed on the periphery of the second well and the fourth well; and
a diffusion layer of the second conduction type, and formed so as to accommodate the drain, and having impurity concentration lower than impurity concentration of the drain.

2. The solid-state image sensing device according to claim 1, wherein the diffusion layer of the second conduction type is formed on an area excluding the second well.

3. The solid-state image sensing device according to claim 1, wherein the diffusion layer of the second conduction type is formed so as to accommodate the drain in the periphery of the gate.

4. The solid-state image sensing device according to any one of claims 1 through 3, further comprising:
a diffusion layer of the first conduction type, and formed below the gate and in the fourth well, and having impurity concentration higher than the fourth well.
